(19) United States
(12) Patent Application Publication
(10) Pub. No.: US 2006/0186437 A1
(43) Pub. Date: Aug. 24, 2006

(54) Bipolar transistor

(75) Inventor: Shigetaka Aoki, Kashiwara-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/354,049

(22) Filed: Feb. 15, 2006

(30) Foreign Application Priority Data
Feb. 23, 2005 (JP) 2005-047640

(51) Int. Cl. H01L 31/109

(52) U.S. Cl. 257/197

(57) ABSTRACT

A bipolar transistor, wherein a outgoing electrode is made of a polycrystalline Si film, and C atom, or Ge atom together with C atom are added in the polycrystalline Si film.

### BACKGROUND OF THE INVENTION

1. Field of the Invention

The present invention relates to a bipolar transistor in which poly-silicon is used as a outgoing electrode.

2. Description of the Related Art

In recent years, there is a growing demand for a higher frequency and lower power consumption in a bipolar transistor. In the bipolar transistor in which poly-silicon is used as a outgoing electrode, reduction of a parasitic capacitance, which is demanded in a micro-fabrication of the transistor, can be facilitated. Therefore, the bipolar transistor has been increasingly adopted in a field of high frequency as a transistor structure suitable for a higher operation speed.

Below is described an example for a general structure of the bipolar transistor in which the poly-silicon is used as the outgoing electrode. FIG. 4 is a sectional view illustrating a structure of an emitter section and a base section in a bipolar transistor using the poly-silicon as the outgoing electrode and comprising an intrinsic base layer resulting from epitaxial growth. The structure is recited in No. H06-69225 of the Publication of the Unexamined Japanese Patent Applications.

A collector layer 11 is formed in a Si substrate, and a region 12 to separate element, such as a shallow trench, is formed in a periphery of the collector layer 11. Further, an intrinsic base layer 13 and a base poly-silicon electrode (outgoing electrode) 14 are formed on the collector layer 11.

The intrinsic base layer 13 is doped with a P-type impurity such as B (boron) by means of a selective epitaxial method of Si growth. The base silicon electrode (outgoing electrode) is doped with a P-type impurity such as B atom for building a connection between the intrinsic base layer 13 to a metal electrode 20.

Further, an emitter layer 15 is formed in the intrinsic base layer 13. Over the emitter layer 15 is formed an emitter poly-silicon electrode (outgoing electrode) 17 doped with an N-type impurity such as a P (phosphorous) atom. The emitter poly-silicon electrode (outgoing electrode) 17 is provided for connecting the emitter layer 15 to the metal electrode 20. The emitter layer 15 is formed in such a manner that the emitter poly-silicon electrode 17 is formed and thereafter subjected to a heat treatment so that the impurity is diffused from the emitter poly-silicon electrode 17 into the intrinsic base layer 13.

Further, an insulation film 16, such as an oxide film or a nitride layer, is formed between the emitter silicon electrode 17 and the base poly-silicon electrode 14. The insulation film 16 is provided to electrically insulate the emitter poly-silicon electrode 17 and the base poly-silicon electrode 14 from each other. Further, a silicide layer 18, such as Co (cobalt) silicide, is formed on the emitter poly-silicon electrode 17 and the base poly-silicon electrode 14. The silicide layer 18 is provided to reduce a contact resistance to the metal electrode 20. The silicide layer 18 is connected to the metal electrode 20 via a contact hole 19 in which W (tungsten) or the like is embedded.

The foregoing bipolar transistor is a promising technology from a view of improving an electrical property because it is easy to make a reduction of the parasitic capacitance by micro-fabrication. However, the bipolar transistor has such a disadvantage that a parasitic resistance is easily increased as described below. Before the disadvantage is described, below is given a description of components constituting an emitter parasitic resistance Re in the bipolar transistor in which the poly-silicon is used as the outgoing electrode referring to FIG. 4.

Re₁ denotes a contact resistance between the contact hole 19 formed for the connection to the metal electrode 20 and the emitter poly-silicon electrode 17, Re₂ denotes a resistance of the emitter poly-silicon electrode 17, Re₃ denotes a contact resistance between the emitter poly-silicon electrode 17 and the emitter layer 15, and Re₄ denotes a resistance of the emitter layer 15. The emitter parasitic resistance Re generally represents the sum of these resistances as shown in the following formula.
Re=Re₁+Re₂+Re₃+Re₄

The emitter poly-silicon electrode 17 is formed by means of the LP-CVD method, which is the chemical vapor deposition under reduced pressure. The LP-CVD method includes a heat treatment at approximately 500° C.-700° C., and an oxide film (interface oxide film) 21 having a thickness of approximately a few nm is thereby inevitably deposited in an interface between the poly-silicon and the silicon layer as an underlayer thereof as shown in FIG. 5A. The interface oxide film 21 is deposited as a result of chemical reactions with oxygen remained in a load lock chamber and a reactor when a temperature is stable prior to the growth of the poly-silicon. Therefore, it is technically difficult to remove the interface oxide film 21.

Because the interface oxide film 21 acts as a barrier for electron or hall conduction, the emitter contact resistance Re₃ increases in an extent due to the presence of the interface oxide film 12. The components other than the emitter contact resistance Re₃ can be reduced to a satisfactory level by, for example, sufficiently increasing an impurity concentration. Therefore the emitter contact resistance Re₃ has a particularly larger occupation rate than the other components constituting the emitter parasitic resistance Re. Consequently, it is effective to reduce the emitter contact resistance Re₃, namely to prevent the increase of the resistance due to the interface oxide film 21 in order to reduce the emitter parasitic resistance Re.

In the bipolar transistor comprising the poly-silicon electrode, the following methods are used as a method to prevent the increase of the contact resistance due to the interface oxide film, for example, as shown in No. 2004-221195 of the Publication of the Unexamined Japanese Patent Applications.
Method 1: The method to apply a higher temperature to an annealing treatment when an impurity is diffused.
Method 2: The method to increase an impurity concentration in a poly-silicon electrode.

### SUMMARY OF THE INVENTION

Generally, in the bipolar transistor having the poly-silicon electrode the annealing treatment at 800° C. or more (activation annealing) is applied to the emitter silicon electrode 17 after it is formed so that the impurity in the emitter poly-silicon electrode 17 is activated and diffused from the emitter poly-silicon electrode 17 onto the underlayer 13 side (solid phase diffusion), and then the emitter layer 15 is formed.

As shown in FIG. 5B, the interface oxide film 21 in the poly-silicon/silicon interface is destroyed during the activation annealing, and a silicon oxide 22 is formed in consequence of ball-up. Then, a thin epitaxial layer 23 having a thickness of approximately a few nm is partly formed from the silicon side through to the poly-silicon side in the poly-silicon/silicon interface (ball-up phenomenon).

The generation of the ball-up phenomenon serves to improve a contact property between the poly-silicon and silicon, which effectively reduces the contact resistance. As the destruction of the interface oxide film resulting from the ball-up phenomenon is larger and larger, the contact resistance can be effectively reduced more and more. The “Method 1” and the “Method 2” described earlier promote the ball-up phenomenon. However, the “Method 1” and the “Method 2” are effective to reduce the emitter contact resistance Re₃, but there are the following problems.

According to the “Method 1” and “Method 2”, the temperature in the activation annealing is increased or the concentration of the impurity in the poly-silicon electrode 17 is increased in order to reduce the contact resistance. According to it, the diffusion of the impurity onto the base layer 13 side as the underlayer is promoted as shown in FIGS. 6A and 6B. As a result, there causes the disadvantages thereby that a depth of the emitter diffusion increases, and a variability of the emitter diffusion also increases.

Thus, in the conventional technology as the “Method 1” and the “Method 2”, it causes degradation of an electrical property of the bipolar transistor such as reduction of a high-frequency property, increased variability of a current amplification factor h_{FE}, and reduction of a voltage resistance between the collector and the emitter. Therefore, it was not possible to sufficiently reduce the contact resistance without sacrificing the performance of the transistor in the conventional technology.

Further, P (phosphorous) atom is often used in general as the emitter impurity in the bipolar transistor. P atom is particularly easily paired with interstitial Si (interstitial Si—P pair), which is generated in vicinity of the interface of the poly-silicon/silicon substrate and in the poly-silicon film in the activation annealing. When the pair is formed, the diffusion of P atom advances (abnormal diffusion), and the performance of the transistor remarkably deteriorates due to the increase of the emitter diffusion and its variability.

Therefore, a main object of the present invention is to effectively reduce a parasitic resistance while preventing degradation of a performance of a bipolar transistor in which a outgoing electrode is formed from a polycrystalline film without reduction of a high-frequency property (f_{T}, fₘₐₓ) and a collector-emitter voltage resistance and variability of a current amplification factor h_{FE}, and increase of variability in the performance.

In order to achieve the foregoing object, a outgoing electrode is formed from a polycrystalline film, and the polycrystalline film contains Si atom as a main component thereof and C atom are added to the polycrystalline film in a bipolar transistor according to the present invention.

Thereby, the following operations are given by the present invention. C atom introduced into the polycrystalline film is more active than P (phosphorous) atom in capturing interstitial Si atom generated in an activation annealing. Therefore, the capture of the interstitial Si atom by C atom prevents abnormal diffusion of P atom , shallows a depth profile of an impurity and steepens a poly-silicon/silicon interface. Thereby, a higher temperature in the activation annealing is achieved, segregation of P atom (such a phenomenon that a composition of a precipitation-solidified part is different according to a temperature fall over time in each of liquid phase having different compositions respectively in an equilibrium state) is promoted. The phenomenon accelerates destruction of an interface oxide film (ball-up phenomenon), as a result of which an emitter contact resistance can be reduced. Thereby, a parasitic resistance can be reduced without reducing the property of the transistor and increasing the variability.

In the bipolar transistor according to the present invention, the polycrystalline film is further doped with Ge atoms in the foregoing constitution.

Thereby, the following operations are given by the present invention. The mixture of Ge atom increases mobility. Further, Ge atom does not react with the interstitial Si atom and P atom, and therefore, are not paired with these atoms. Therefore, the addition of Ge atom together with C atom can reduce the emitter resistance much more. Since Ge atom and C atom are supplied from different types of gas as their sources, addition quantity of the respective atoms can be independently controlled. Further, as the Ge atom attached to a surface of the Si atom serves as a reaction site and thereby a film growth rate is increased, C atom can be more actively introduced and a film-forming process can be carried out at a lower temperature.

In the foregoing constitution, the polycrystalline film comprises first and second layers having different C-atom concentrations respectively, wherein it is preferable that the C-atom concentration of the first layer in contact with a semiconductor layer as an underlayer of the polycrystalline film is higher than the C-atom concentration of the second layer.

There is a tendency that a resistance of the polycrystalline film itself increases as the addition quantity of C atom increases. As a result, the resistance reduction effect may not be sufficiently obtained by use of the destruction of the interface oxide film due to the addition of C atom (ball-up phenomenon). Further, the addition of C atom results in a factor for inhibiting a silicide reaction in the formation of a silicide film which reduces a contact resistance between a contact hole and the electrode formed from the polycrystalline film, and it may lead to a thinner thickness of the silicide film and a quality degradation of the film. In order to avoid the possible disadvantages, the polycrystalline film is made of the two-layer structure so that not only a favorable property can be obtained in the silicide reaction but also the effect of the resistance reduction is maintained wherein the addition amount of C atom is reduced to a necessary minimum quantity. Here, it is preferable that the concentration of C atom in the second layer is zero.

Further, in the foregoing constitution, it is preferable that the concentration of C atom has an inclination in the polycrystalline film so that the concentration is a maximum value at an interface between the polycrystalline film and the semiconductor layer as an underlayer thereof, and becomes zero in the polycrystalline film.

By giving the concentration of C atom a peak level in the vicinity of the interface between the polycrystalline film and the silicon, the P—Si pair is selectively isolated from each other in the vicinity of the interface in order to increase the segregation of P atom in the vicinity of the interface. Thereby, the destruction of the interface oxide film resulting from the ball-up can be more effectively accelerated.

In the foregoing constitution, an addition amount of C atom y in the composition of the polycrystalline film is preferably 0.001≦y≦0.03. Because C atom are added in order to capture the interstitial Si atom generated in the activation annealing, therefore the amount of C atom can be equal to or more than 0.1 atom %. The addition quantity of C atom is preferably at 3 or less atom % in view of the quality degradation of the poly-silicon film and inconsistency with a conventional film-forming process.

In the foregoing constitution, an addition amount of Ge atoms x in the composition of the polycrystalline film is preferably 0.05≦x≦0.3. The purposes to add Ge atom is to reduce a resistivity of the polycrystalline film and facilitate the introduction of C atom. Therefore, the amount of Ge atom to be introduced is preferably at least 5 atom %. As the amount of Ge atom increases, difficulties are more likely to be generated in the deposition process, such as the quality degradation of the poly-silicon film and the slowdown of the growth rate. Therefore, the amount of Ge atom is preferably at 30 or less atom % in order to attain the effect of the present invention avoiding the difficulties.

Further, in the foregoing constitution, a thickness of the first layer is preferably at least 10 nm and at most 100 nm. A lower limit value of the thickness is setup as a thickness neccesary to obtain the effect to control the abnormal diffusion due to the capture of the interstitial Si. An upper-limit value of the thickness is set up as an upper-limit value to control the increase of the emitter contact resistance Re₂.

Further a thickness of the second layer is preferably at least 50 nm and at most 300 nm. A lower-limit value of the thickness is set up as a thickness capable of controlling the inhibition of the silicide reaction due to C atom, more specifically, is set up under consideration of the diffusion of C atom during a heat treatment and the diffusion of reactive species in the silicide reaction. An upper-limit value of the thickness is set up in view of restrictions caused by fabrication of the emitter outgoing electrode.

A bipolar transistor according to the present invention is a bipolar transistor in which a outgoing electrode is formed from a polycrystalline film, wherein the polycrystalline film consists of the Si atom as a main component thereof, and further contains an impurity atom as one of the conductive types and an atom having a stronger bonding force to the Si atom than that of the impurity atom.

In the foregoing constitution, the atoms having the stronger bonding force to Si atom are preferably oxygen atom and fluorine atom.

The atoms to control the diffusion of P atom are not limited to C atom in order to obtain the effect of the present invention. A similar effect can be obtained as far as the atoms have a stronger bonding energy to the interstitial Si than the interstitial Si—P pair, such as the oxygen atom, fluorine atom and the like.

According to the present invention, in the bipolar transistor in which the outgoing electrode is formed from the polycrystalline film, the reduction of the parasitic resistance can be easily realized without the reduction of the transistor property (f_{T}, fₘₐₓ, f_{FE}, and the like).

As mentioned above, the present invention is useful for the bipolar transistor in which the polycrystalline film is used as the outgoing electrode.

### BRIEF DESCRIPTION OF THE DRAWINGS

The other objects of the invention except the ones described above will become clear by the following description of preferred embodiments of the invention and be shown in the attached Claims. A number of benefits not recited in this specification will come to the attention of the skilled in the art by carrying out the present invention.

FIG. 1A is a sectional view illustrating a structure of an emitter section (base section) in a bipolar transistor according to embodiments 1 and 2 of the present invention.

FIG. 1B shows an impurity concentration profile of the emitter section (base section) in the bipolar transistor according to the embodiments 1 and 2.

FIG. 2A is a sectional view illustrating a structure of an emitter section (base section) in a bipolar transistor according to an embodiment 3 of the present invention.

FIG. 2B shows an impurity concentration profile of the emitter section (base section) in the bipolar transistor according to the embodiment 3.

FIG. 3A is a sectional view illustrating a structure of an emitter section (base section) in a bipolar transistor according to an embodiment 4 of the present invention.

FIG. 3B shows an impurity concentration profile of the emitter section (base section) in the bipolar transistor according to the embodiment 4.

FIG. 4 is a sectional view illustrating structures of an emitter section, a base section in a conventional bipolar transistor in which poly-silicon is used as a outgoing electrode and the components constituting an emitter parasitic resistance.

FIG. 5A shows an interface oxide film formed due to a ball-up phenomenon in a poly-silicon/silicon interface, which is a problem of the present invention to be solved.

FIG. 5B shows destruction of the interface oxide film due to the ball-up phenomenon in the poly-silicon/silicon interface, which is a problem of the present invention to be solved.

FIG. 6A is a sectional view illustrating structures of an emitter section and a base section in a bipolar transistor, which is a problem of the present invention to be solved.

FIG. 6B shows an impurity concentration profile of the emitter section and the base section in the bipolar transistor, which is a problem of the present invention to be solved.

### DETAILED DESCRIPTION OF THE INVENTION

Hereinafter, preferred embodiments of the present invention are described referring to the drawings. The description is given based on a bipolar transistor of NPN type.

### Embodiment 1

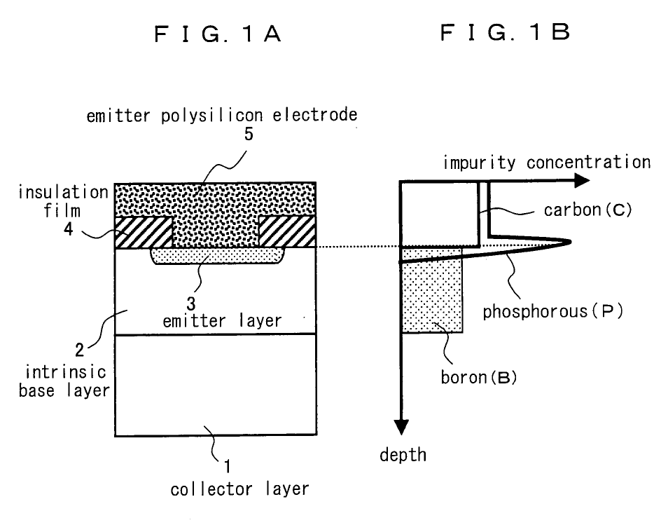

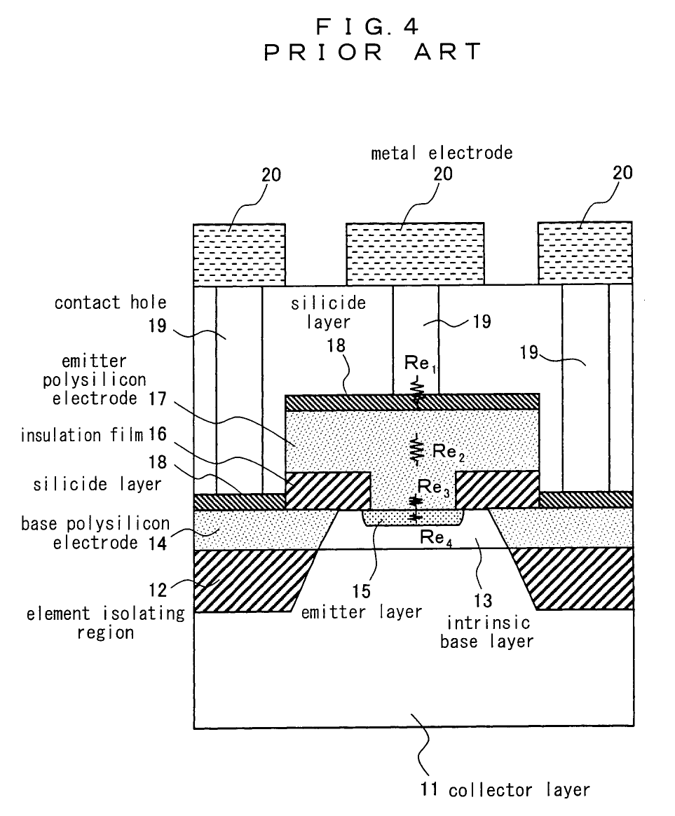

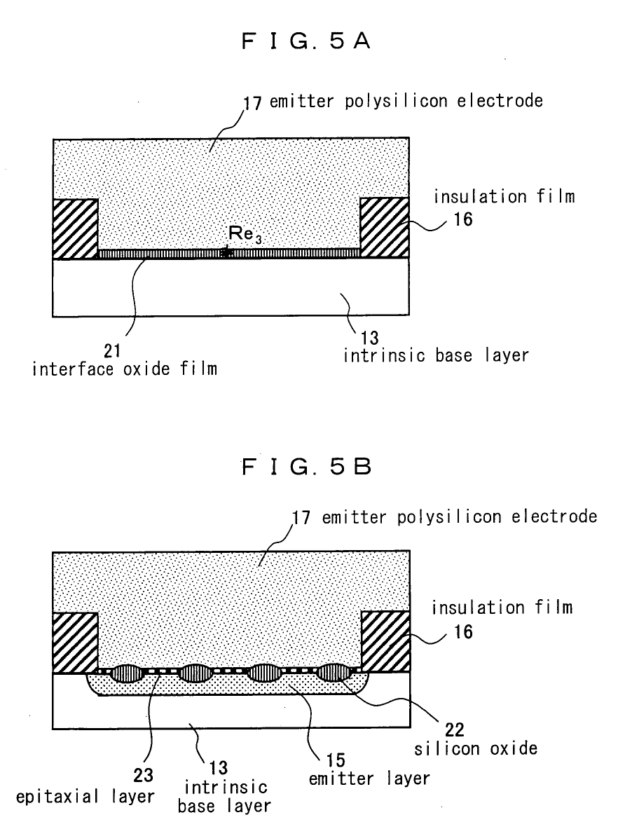

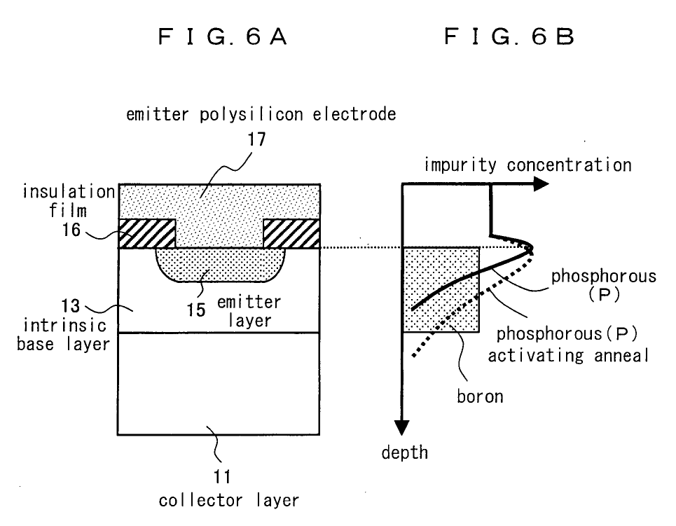

FIG. 1A is a sectional view illustrating a structure of an emitter section in a bipolar transistor according to an embodiment 1 of the present invention. FIG. 1B shows an impurity concentration profile. In FIGS. 1A and 1B, a reference numeral 1 denotes a collector layer formed in a Si substrate, a reference numeral 2 denotes an intrinsic base layer doped with a P-type impurity such as boron (B) by means of epitaxial growth method on the collector layer 1, a reference numeral 3 denotes an emitter layer formed in the intrinsic base layer 2, a reference numeral 4 denotes an insulation film, and a reference numeral 5 denotes an emitter poly-silicon electrode. The emitter layer 3 is fabricated in such a manner that the emitter poly-silicon electrode 5 is formed and heat treatment is carried out so that an impurity is diffused from the emitter poly-silicon electrode 5 into the intrinsic base layer 2. Referring to any other component in the drawings, the conventional structure shown FIG. 4 is used.

In the present embodiment, a small amount of C (carbon) atom is added into the poly-silicon electrode 5 used as the outgoing electrode. The poly-silicon electrode 5 has the composition of Si_{(1-y)}Cy(0<y<<1)

The following effect is obtained by the addition of C atom. C atom introduced into the poly-silicon electrode 5 is more easily paired with interstitial Si (Si—P pair) produced in vicinity of a poly-silicon/silicon interface and in a poly-silicon film than P atom in an activation annealing treatment (capture of the interstitial Si by the C atom). Because of the foregoing characteristic, a concentration of the interstitial Si in the poly-silicon/silicon interface can be made lower than in the conventional technology wherein abnormal diffusion of P atom is controlled. As shown in FIG. 1B, depth profile of an impurity can be made shallow by the addition of C atom and steepens at the poly-silicon/silicon interface in comparison to the conventional technology.

As the abnormal diffusion of P atom is thus effectively controlled, a temperature can be increased in the activation annealing while an emitter diffusion length is maintained at a conventional level. Then, the destruction of the interface oxide film (ball-up phenomenon) is accelerated and thereby an emitter contact resistance Re₃ can be reduced.

Further, as the abnormal diffusion of P atom is thus effectively controlled, segregation of P atom into the poly-silicon/silicon interface (increase of a concentration of P atom in the interface) increases, which also accelerates the destruction of the interface oxide film. As a result, the emitter contact resistance Re₃ can be further reduced.

C atom are added in order to capture the interstitial Si atom generated in the activation annealing. Therefore, a silicon carbide film (SiC film) is unnecessary to have the composition of the stoichiometry ratio 1:1, which is used to be acted as a hetero emitter layer. A sufficient effect for capture can be obtained as far as an amount of C atom is added at least 0.1 atom % (y=0.01). Further, the amount of C atom is preferably at most 3 atom % (y=0.03) in terms of degradation of a quality of the poly-silicon film and consistency with a conventional film-forming process.

Thus, such a small amount of C atoms is enough to obtain the effect of the present invention. Therefore, C atom can be easily introduced into the poly-silicon electrode 5 within the range of the conventional film-forming technology in such a manner that process gas containing C atom such as methylsilane is added at the same time as the formation of the poly-silicon electrode 5. Further, any change of a film-forming process such as increase of a temperature is unnecessary and thereby, a risk on degradation of a transistor property can be avoided. Accordingly, the constitution of the present embodiment can be easily applied to a conventional silicon LSI process.

As described, according to the present embodiment, only a parasitic resistance can be reduced without the degradation of the transistor property and increase of variability by adding the small amount of C atoms to the poly-silicon electrode.

### Embodiment 2

In an embodiment 2 of the present invention, Ge (germanium) atom as well as C atom are added to the poly-silicon electrode 5 as the outgoing electrode. Namely, the poly-silicon electrode 5 has the composition of Si_{(1-x-y)}GeₓC_{y}(0<x<1,0<y <<1). An emitter resistance Re can be reduced much more by addition of Ge atom and C atom at the same time. As another advantage, C atom can be added under easier conditions of the film-forming process than in the embodiment 1.

It is generally known that a Ge semiconductor has a mobility larger than that of the Si semiconductor. Further, it is also well known that the mobility is increased as the cntent of the Ge is increased in a semiconductor made of crystal mixture of Si and Ge. Such a phenomenon can be seen in the same manner in crystal grains in the polycrystalline film. With respect to a conventional poly-silicon electrode, a film resistivity become smaller in the case of a poly-silicon germanium electrode containing germanium in comparison to a poly-silicon electrode without germanium under the conditions that the both electrodes are doped with an equal amount of impurity.

Therefore, a poly-silicon electrode resistance Re₂ among the components consisting of the emitter parasitic resistance can be reduced by fabricating a poly-silicon germanium electrode 4 wherein Ge atom is added to the poly-silicon electrode 5. The effect described above can be obtained maintaining the effect according to the embodiment 1 because Ge atom does not react with the interstitial Si atom , P atom and the like and is not paired with these atoms even though Ge atom is added to the poly-silicon electrode 5. As a result, the emitter resistance Re can be further reduced in comparison to the embodiment 1.

With regard to addition of Ge atom to the poly-silicon electrode 5, the resistance can be easily reduced by means of the conventional deposition process by adding process gas containing Ge atom such as germane (GeₙH₂ₙ₊₂) at the same time as the formation of the poly-silicon electrode. Further, as a different types of gas source is used between the Ge atom and the C atom, amounts of the respective atoms to be added can be approximately controlled independently.

Further, because C atom cannot be efficiently introduced during the formation of the poly-silicon electrode 5, it is difficult to control the addition of C atom when the C tom alone is added. However, when Ge atom is further added at the same time, the Ge atom attached to a surface of the Si atom acts as a reaction site, which accelerates a film growth rate. As a result, C atom can be more actively introduced, and the temperature in the film-forming process can be lowered in comparison to a conventional poly-silicon growth.

The object of the addition of Ge atom is to reduce the resistivity of the poly-silicon electrode 5 and facilitate the introduction of C atom. Therefore, the amount of Ge atom is preferably added at least 5 atom % (x=0.05).

As the addition quantity of Ge atom increases more and more, some difficulties is caused in the film-forming process such as the quality degradation of the polysilicon film and the decrease of growth rate. In order to obtain the effect of the present invention avoiding these difficulties, the amount of Ge atom is preferably added at most 30 atom % (x=0.3). The amount of C atom to be added is basically the same as described in the embodiment 1 and smaller than the amount of Ge atom added (y<x).

As described above, according to the embodiment 2, the parasitic resistance of the bipolar transistor can be reduced much more than in the case that C atom alone are added by a simultaneous addition of Ge atom and C atom to the poly-silicon electrode 15.

### Embodiment 3

It is generally known that the addition of C atom to the poly-silicon increases the resistivity of the film. Then, the resistance Re₂ of the poly-silicon electrode 5 increases as the addition amount of C atom become more and more, which, in some case, does not achieve the sufficient effect of the emitter resistance reduction due to the addition of C atom.

A silicide film 18 is formed on an emitter poly-silicon electrode 17 in order to reduce a contact resistance Re₁ between a contact hole 19 and the emitter poly-silicon electrode 17 as shown in the conventional technology in FIG. 4. However, when C atom is added in the such structure mentioned above, a silicide reaction is inhibited, and thereby the disadvantages is caused such as a reduction of thickness and a quality degradation of the silicide film 18.

An embodiment 3 of the present invention solves the foregoing disadvantages that may be possible to be generated in the embodiments 1 and 2 and thereby further improves the effect of the present invention. The poly-silicon electrode is formed from two layers different in concentrations of C atom and Ge atoms in the present embodiment.

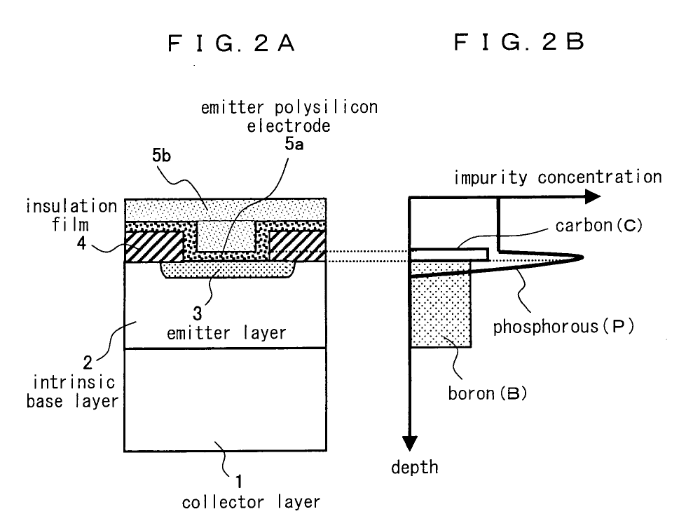

FIG. 2A is a sectional view illustrating a structure of an emitter section in a bipolar transistor according to the embodiment 3. FIG. 2B shows an impurity concentration profile. Any reference numeral shown in FIGS. 2A and 2B, which is identical to those shown in FIG. 1 according to the embodiment 1, refers to the same component and is not described in detail here.

In the embodiment 3, the outgoing electrode consists of a poly-silicon electrode (second layer) 5b in which Ge atom alone are added (C atoms are not added) formed on a poly-silicon electrode (first layer) 5a in which the only C element is added or C atom and Ge atoms are both added. Thereby, a region where C atom is added in the poly-silicon electrode is limited to the poly-silicon/silicon interface.

By taking the structures shown in FIGS. 2A and 2B, the silicide reaction on the surface of the poly-silicon film is generated in the same manner as the conventional case wherein C atom is not added while the effect to reduce the contact resistance is maintained in the vicinity of the poly-silicon/silicon interface according to the embodiments 1 and 2. Thereby, such an inconvenience is avoided that the contact resistance Re₁ between the contact hole and the emitter poly-silicon electrode is increased.

Further, by limiting the region where C atom is added to a minimum required instead of the entire poly-silicon electrode, the increase of the resistance of the poly-silicon electrode can be controlled to such a level that does not cause any problem in practical use.

As described above, according to the structures shown in FIG. 2A and 2B, the effect of reducing the emitter resistance by the addition of C atom can be obtained without any inconvenience due to the addition of C atom.

A thickness capable of obtaining the effect to control the abnormal diffusion due to the capture of the interstitial Si is necessary as a lower-limit value of a thickness of the poly-silicon electrode (first layer) 5a with addition of C atom. The lower-limit value of the thickness is preferably 10 nm. An upper-limit value of the thickness is preferably 100 nm in order to control the increase of the emitter contact resistance Re₂.

Further, a thickness capable of controlling the inhibition of the silicide reaction due to C atom is necessary as a lower-limit value of a thickness of the poly-silicon electrode (second layer) 5b without addition of C atom. Practically, the lower-limit value of the thickness is preferably 50 nm in view of the diffusion of C atom by the heat treatment and the diffusion of the reactive species during the silicide reaction. On the other hand, An upper-limit value of the thickness is preferably 300 nm because of the restrictions to fabricate the emitter outgoing electrode.

The regions having the different concentrations of C atom each other can be easily formed by the such method that a flow rate of source gas of C atom is changed during the film-forming process.

Though the poly-silicon electrode 5b without addition of C atom may not necessarily contain Ge atom, it is preferable that Ge atom is added in order to obtain the effect according to the embodiment 2.

Further in the foregoing description, the poly-silicon electrode (second layer) 5b is made to be the layer which contains Ge atom alone without addition of C atom. This is the structure in order to obtain the most desirable effect but the poly-silicon electrode (second layer) 5b is not limited to the one without addition of the C toms. In short, the concentration of C atom in the poly-silicon electrode (first layer) 5a in contact with the semiconductor layer (emitter layer 3) as an underlayer thereof is higher than the one of the C toms in the poly-silicon electrode (second layer) 5b.

### Embodiment 4

An embodiment 4 of the present invention is to further improve the effect obtained in the embodiment 3.

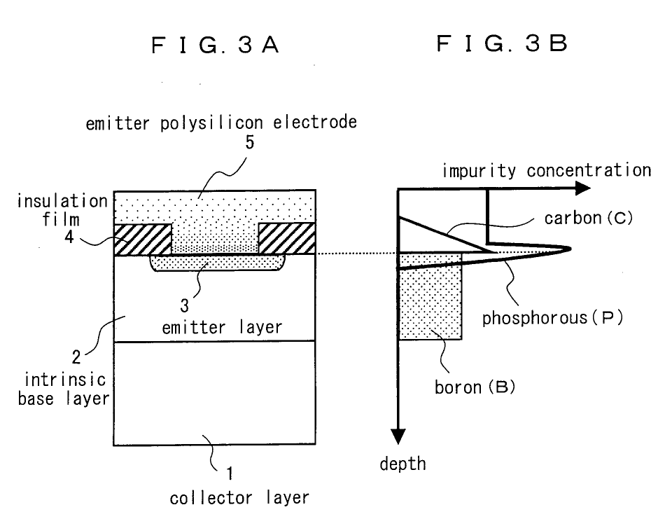

FIG. 3A is a sectional view illustrating a structure of an emitter section in a bipolar transistor according to the embodiment 4. FIG. 3B shows an impurity concentration profile. Any reference numeral shown in FIGS. 3A and 3B, which is identical to those shown in FIG. 1 according to the embodiment 1, denotes the same component and is not described in detail here.

In the embodiment 4, the concentration of C atom in the region with addition of C atom has such an inclination structure that the concentration is at a maximum level in the poly-silicon interface, and the concentration reduces gradually from the interface toward the surface of the poly-silicon electrode 5 to finally become zero in the emitter poly-silicon electrode 5. The following effects are obtained by giving the inclination structure to the concentration of C atom.

The interstitial Si atoms generated in the vicinity of the polylisicon/silicon interface and in the poly-silicon electrode in the activating anneal are paired with the impurity such as P atom in the poly-silicon electrode and diffuse into the silicon film underlayer. The P—Si pair can be isolated selectively from each other in the vicinity of the interface of the poly-silicon/silicon substrate by giving a peak to the concentration of C atom in the vicinity of the interface as in the present embodiment. Thereby, the segregation of P atom in the vicinity of the interface is increased and the destruction of the interface oxide film due to the ball-up can be more effectively accelerated.

Further, the foregoing advantage also serves to minimize the unfavorable increase of the restivity of the poly-silicon electrode generated by the addition of C atom. As a result, the emitter parasitic resistance Re can be more effectively reduced than in the embodiments 1-3.

It is unnecessary for the concentration inclination of C atom to change continuously as shown in FIGS. 3A and 3B. The same effect can be obtained in a structure where the concentration changes step by step, as an example of a laminate structure made of the films with different concentrations respectively.

The concentration inclination of C atom can be easily realized in such a manner that the flow rate of the gas is changed step by step during the film-forming process. The concentration inclination of C atom does not cause any inconvenience such as the degradation of the transistor property.

The poly-silicon electrode 5b without addition of C atom may not necessarily contain Ge atom, however, it is preferable that Ge atom is added in order to obtain the effect of the embodiment 2.

The foregoing description is given to the emitter poly-silicon electrode, however, it can be applied to a base poly-silicon electrode in the same manner.

The explanations of the embodiments 1-4 are given based on the method of adding C atom and Ge atom during the formation of the poly-silicon electrode (in-situ doping). However, the same effect can be obtained in such a manner that C atom is introduced by means of the ion implantation method or the like after the poly-silicon film is formed.

Further, the explanations of the embodiments 1-4 are given based on the NPN transistor, however, the same effect can be obtained in the case of a P-type impurity such as B (boron). Therefore, the same effect can be also obtained in the case of a PNP transistor used as the outgoing electrode where a poly-silicon film doped with B atom and an NPN transistor used as the outgoing electrode where a poly-silicon film doped with B atom.

The explanations about embodiments 1-4 were given using C atom as a atom to control the diffusion of P atom or B atom The effect according to the present invention is not limited to C atom, and the same effect can be obtained with regard to an atom like an oxygen, a fluorine and so on having a stronger bonding force with the interstitial Si than in the interstitial Si—P pair or interstitial Si—B pair.

In the description of the foregoing embodiments, the explanations is given to the example where the present invention is applied to the emitter poly-silicon electrode, however, it can be applied to a base poly-silicon electrode in the same manner.

Though an explanation is given in detail to the most preferable example, it will be understood that the various modifications may be made about combination and arrangement of the parts in the preferred embodiments, and it is intended to cover all such modifications as fall within the true spirit and scope of this invention in the appended claims.

What is claimed is:

1. A bipolar transistor, wherein
a outgoing electrode is made of a polycrystalline film, and
the polycrystalline film contains Si atom as a main component thereof and C atoms is added to the polycrystalline film.

2. A bipolar transistor of claim 1, wherein
the polycrystalline film further contains Ge atoms.

3. A bipolar transistor of claim 2, wherein
the polycrystalline film comprises first and second layers having different concentrations of C atom respectively, and
the concentration of the C atom in the first layer in contact with a semiconductor layer as an underlayer of the polycrystalline film is higher than the one of the second layer.

4. A bipolar transistor of claim 3, wherein
the concentration of the C atom in the second layer is zero.

5. A bipolar transistor of claim 2, wherein
the concentration of the C atom in the polycrystalline film has such an concentration inclination that the concentration becomes a maximum level at an interface between the polycrystalline film and a semiconductor layer as an underlayer thereof and zero in the polycrystalline film.

6. A bipolar transistor of claim 2, wherein
an addition quantity of C atom y in a composition of the polycrystalline film is 0.001≦y≦0.03.

7. A bipolar transistor of claim 2, wherein
an addition quantity of Ge atom x in a composition of the polycrystalline film is 0.05≦x≦0.3.

8. A bipolar transistor of claim 3, wherein
a thickness of the first layer is at 10 nm or above and 100 nm or less.

9. A bipolar transistor of claim 3, wherein
a thickness of the second layer is 50 nm or above and 300 nm or less.

10. A bipolar transistor, wherein
a outgoing electrode is made of a polycrystalline film, and
the polycrystalline film contains Si atom as a main component thereof, and further contains impurity atoms as one of the conductive types and atoms having a stronger bonding force with the Si atom than that of the impurity atoms.

11. A bipolar transistor of claim 10, wherein
the atoms having the stronger bonding force to Si atom are oxygen atom or fluorine atom.
